(19) United States
(12) Patent Application Publication
(10) Pub. No.: US 2017/0330925 A1
(43) Pub. Date: Nov. 16, 2017

(54) DOUBLE-SIDE OLED DISPLAY AND MANUFACTURE METHOD THEREOF

(71) Applicant: Wuhan China Star Optoelectronics Technology Co., Ltd., Wuhan (CN)

(72) Inventor: Yuejun TANG, Shenzhen (CN)

(73) Assignee: Wuhan China Star Optoelectronics Technology Co., Ltd., Wuhan (CN)

(21) Appl. No.: 15/186,458

(22) Filed: Jun. 18, 2016

(30) Foreign Application Priority Data
May 10, 2016 (CN) 2016103077199

(51) Int. Cl. H01L 27/32; H01L 51/00

(52) U.S. Cl. CPC H01L 27/3267; H01L 51/0097; H01L 27/3276; H01L 2227/323

(57) ABSTRACT

The disclosure discloses a double-side organic light-emitting diode (OLED) display and a manufacture method thereof. The double-side OLED display includes a substrate, an OLED layer and a packaging layer overlapped in sequence; the OLED layer includes a first display region and a second display region; the double-side OLED display has a bending region, the bending region is applied to bend the double-side OLED display inwards, to place the first display region and the second display region on two separate flat surfaces. According to the previous method, the disclosure can make the OLED thin and light, reduce time of manufacture and enhance productivity.

### FIELD OF THE DISCLOSURE

The disclosure relates to a display technical field, and more particularly to a double-side OLED display and a manufacture method thereof.

### BACKGROUND OF THE DISCLOSURE

An organic light-emitting diode (OLED) display is becoming widely applied according with development of information transmission technology and electronic products. A double-side OLED display is pervasive due to advantages of high brightness, quick response, low energy consumption and flexibility.

A conventional double-side OLED display is generally formed by pasting two separate single-side OLED display panels opposite, the sort of double-side display adds a paste process of two panels, which is too tedious to be light and thin, failing to fulfill requirements of electronic products in weight, thickness and volume.

### SUMMARY OF THE DISCLOSURE

The technical issue that the disclosure solves is to provide an OLED display and a manufacture method thereof, which can make an OLED thin and light, reduce time for manufacture and enhance productivity.

To solve the previous technical problem, a proposal offered by the disclosure is: providing a double-side organic light-emitting diode (OLED) display, the double-side OLED display includes a substrate, an OLED layer and a packaging layer overlapped in sequence; the OLED layer includes a first display region and a second display region; the double-side OLED display has a bending region, the bending region is applied to bend the double-side OLED display inwards, to place the first display region and the second display region on two separate flat surfaces.

The substrate corresponding to the bending region is not covered by the OLED layer.

The substrate corresponding to the bending region is not covered by the OLED layer or the packaging layer.

A solder pad region is disposed on the substrate, the OLED layer and the packaging layer do not cover the solder pad region; the solder pad region is connected electrically to the OLED layer, applied to paste a soft circuit board.

The solder pad region is disposed on a side of the substrate away from the bending region, or disposed on the substrate corresponding to the bending region.

The amount of the solder pad region is one or two; when the amount of the solder pad region is one, the solder pad region is connected to the first display region and the second display region electrically; when the amount of the solder pad region is two, the two solder pad regions are connected electrically to the first display region and the second display region respectively.

To solve the technical problem above, another proposal offered by the disclosure is: providing a manufacture method of a double-side organic light-emitting diode (OLED) display, the method includes: forming an OLED layer and a packaging layer on the substrate in sequence; a first display region, a bending region and a second display region are disposed on the substrate; the bending region is applied to make the first display region and the second display region opposite; bending the substrate, the OLED layer and the packaging layer towards inside of the substrate, to make the first display region and the second display region on two separate flat surfaces.

The OLED layer and the packaging layer at least cover the first display region and the second display region.

The packaging layer further covers the bending region, or the OLED layer and the packaging layer further cover the bending region.

A solder pad region is disposed on the substrate; the solder pad region is not covered by the OLED layer or the packaging layer.

The overlapped substrate, OLED layer and packaging layer are bended and folded inwards by disposing the bending region according to the double-side OLED display above, the first display region and the second display region of the OLED layer are disposed on two separate flat surfaces to achieve a function of display on two sides. Because the double-side OLED display is formed by bending and folding a single OLED display panel instead of pasting two display panels in a conventional technique, which can make the OLED thin and light, reduce time for manufacture and enhance productivity.

### BRIEF DESCRIPTION OF THE DRAWINGS

FIG. 1 is a schematic, cross-sectional view of a double-side OLED display according to an embodiment of the disclosure.

FIG. 2-1 and FIG. 2-2 are schematic, cross-sectional views of a double-side OLED display according to another embodiment of the disclosure.

FIG. 3-1 through FIG. 3-5 are plan views of positions of a solder pad region in a double-side OLED display according to an embodiment of the disclosure.

FIG. 4-1 through FIG. 4-5 are schematic, cross-sectional views of a double-side OLED display according to another embodiment of the disclosure.

FIG. 5 is a flow chart of a manufacture method of a double-side OLED display according to an embodiment of the disclosure.

### DETAILED DESCRIPTION OF PREFERRED EMBODIMENTS

Details such as system structures, interfaces and techniques will be provided in following description for illustrating the disclosure thoroughly rather than limitation.

The disclosure provides a double-side OLED display and a manufacture method thereof, though an OLED display is simplified to three structures—a substrate, a light-emitting layer and a packaging layer in embodiments of the disclosure, the three structures can include all components required in a display. Partial structures and components are described in the disclosure for convenience, but no limitation is set: such as the substrate can be thin glass, metal or plastic, the substrate can be an ultra-soft substrate (i.e. organics such as PI, and a hybrid structure consisting of organic and inorganic substances); such as a light-emitting layer includes a TFT control switch, a light-emitting material and so forth, the TFT can be an amorphous silicon or a low temperature poly-silicon process, a structure of the TFT can be a bottom gate type structure or a top gate type structure, the light-emitting material can be various appropriate organic or inorganic materials; a packaging layer can be thin film packaging, outer lid packaging, or even a combination structure of the thin film packaging and the outer lid packaging; the OLED display also includes other components, such as the OLED display can further include a packaging adhesive layer, the packaging adhesive layer is connected to the substrate and a packaging outer lid for preventing vapor from entering.

It is comprehensible that the OLED layer in the disclosure is the light-emitting layer above.

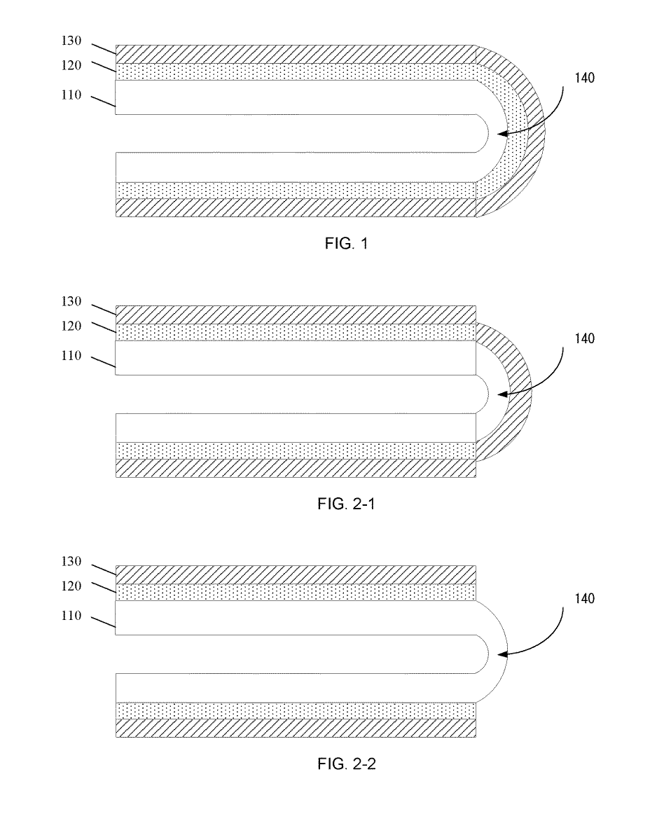

Referring to FIG. 1, FIG. 1 is a schematic, cross-sectional view of a double-side OLED display according to an embodiment of the disclosure. The double-side OLED display in the embodiment includes a substrate 110, an OLED layer 120 and a packaging layer 130 overlapped on the substrate 110. The OLED layer 120 includes an OLED device (the OLED device includes a control system/a signal input terminal and a light-emitting material), the OLED layer 120 is applied to stimulate the light-emitting material to irradiate under control of the control system/signal input terminal; the packaging layer 130 is applied to prevent vapor in the air from entering the double-side OLED display.

The OLED layer 120 includes a first display region and a second display region. The double-side OLED display has a bending region 140, the bending region 140 is applied to bend the double-side OLED display inwards, to place the first display region and the second display region on two separate flat surfaces, in order to make a double-side OLED display to display images on two sides.

Two sections of the substrate 110 after being bent are adjacent, disposed inside of the double-side OLED display.

The first display region and the second display region of the OLED layer 120 can be connected, and disconnected as well.

When the first display region and the second display region are connected, as shown in FIG. 2-1, only one control system/signal input terminal is needed to drive the OLED layer 120 to work, images displayed on the first display region and the second display region can be the same or not, which means the double-side OLED display shows a same image or different images. When the first display region and the second display region are not connected, as shown in FIG. 2-2, two control systems/signal input terminals are needed to drive the first display region and the second display region of the OLED layer 120 respectively to work, images displayed on the first display region and the second display region can be equal or not.

Furthermore, the substrate 110 corresponding to the bending region 140 is not covered by the OLED layer 120 or not covered by the OLED layer 120 as well as the packaging layer 130.

Referring to FIG. 2 as well, FIG. 2 is a schematic, cross-sectional view of a double-side OLED display according to another embodiment of the disclosure.

The substrate 110 corresponding to the bending region 140 can be covered by the OLED layer 120 and the packaging layer 130 (as shown in FIG. 1, the bending region 140 has the OLED layer 120 and the packaging layer 130); the substrate 110 corresponding to the bending region 140 can be merely covered by the packaging layer 130 (as shown in FIG. 2-1, the bending region 140 has the packaging layer 130 instead of the OLED layer 120), the substrate 110 corresponding to the bending region 140 can further be not covered by the OLED layer 120 or the packaging layer 130 (as shown in FIG. 2-2, the bending region 140 does not have the OLED layer 120 or the packaging layer 130).

When the bending region 140 has a wire to connect the first display region and the second display region, and the bending region 140 does not contain the light-emitting layer 120 (the light-emitting material), the bending region 140 can be covered by the packaging layer 130, or not covered by the packaging layer 130 (equally, the packaging layer 130 is optional). It is comprehensible that in the embodiment, an angle formed by the bending region of the double-side OLED display can be determined by materials of the substrate 110, the OLED layer 120 and the packaging layer 130 as well as practical requirements, the first display region and the corresponding second display region except the bending region 140 are parallel, which is not a limitation.

It is comprehensible that an area of the first display region and that of the second display region can be equal or not, which is not a limitation.

The overlapped substrate, OLED layer and packaging layer are bent and folded inwards by disposing the bending region according to the double-side OLED display above, the first display region and the second display region of the OLED layer are disposed on two separate flat surfaces to achieve a function of display on two sides. Because the double-side OLED display is formed by bending and folding a single OLED display panel instead of pasting two display panels in a conventional technique, which can make the OLED thin and light, reduce time of manufacture and enhance productivity.

In another embodiment, a difference from the last embodiment is a solder pad region 111 disposed on the substrate 110. The OLED layer 120 and the packaging layer 130 do not cover the solder pad region 111; the solder pad region 111 is connected electrically to the OLED layer 120, applied to paste a soft circuit board, and connected to an integrated circuit by the soft circuit board, in order to stimulate the OLED layer 120 light-emitting material to irradiate by the integrated circuit.

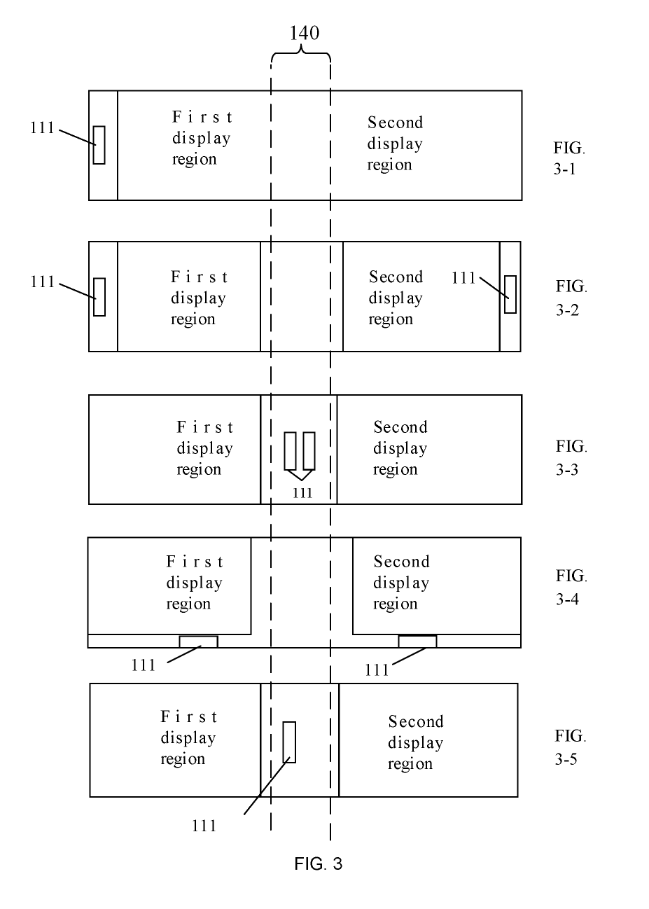

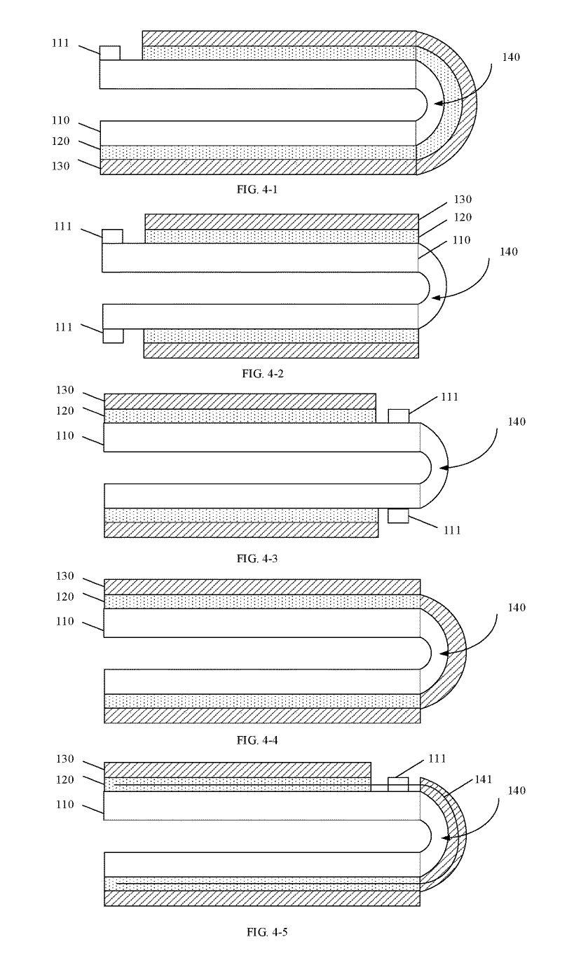

Referring to FIG. 3 and FIG. 4, FIG. 3 is a plan view of positions of a solder pad region in a double-side OLED display according to an embodiment of the disclosure. FIG. 4 is a schematic, cross-sectional view of a double-side OLED display according to another embodiment of the disclosure.

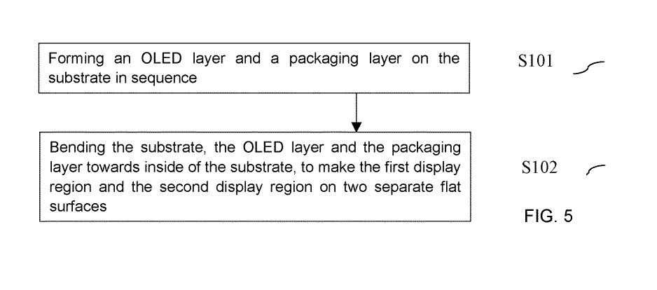

The solder pad region in FIG. 3-1 corresponds to the double-side OLED display in FIG. 4-1, The solder pad region in FIG. 3-2 corresponds to the double-side OLED display in FIG. 4-2, the solder pad region in FIG. 3-3 corresponds to the double-side OLED display in FIG. 4-3, the solder pad region in FIG. 3-4 corresponds to the double-side OLED display in FIG. 4-4, he solder pad region in FIG. 3-5 corresponds to the double-side OLED display in FIG. 4-5.

In FIG. 4-1, the bending region 140 is covered by the OLED layer 120 and the packaging layer 130 (the bending region 140 includes the substrate 110, the OLED layer 120 and the packaging layer 130), in FIG. 4-2 and FIG. 4-3, the bending region 140 is not covered by the OLED layer 120 or the packaging layer 130 (the bending region 140 includes the substrate 110 instead of the OLED layer 120 or the packaging layer 130), in FIG. 4-4 and FIG. 4-5, the bending region 140 is only covered by the packaging layer 130 (the bending region 140 includes the substrate 110 and the packaging layer 130, without the OLED layer 120). As the solder pad region 111 in FIG. 4-5 needs to control the first display region and the second display region, a wire 141 is disposed on the bending region to connect the first display region and the second display region.

In the embodiment, the solder pad region 111 is disposed on a side of the substrate 110 away from the bending region 140, or disposed on the substrate corresponding to the bending region 140, or disposed on the substrate corresponding to where is adjacent to the bending region 140.

The amount of the solder pad region 111 is one or two; when the amount of the solder pad region 111 is one, the solder pad region 111 is connected to the first display region and the second display region electrically, and the first display region and the second display region of the OLED layer 120 can be connected or disconnected; when the amount of the solder pad region is two, the two solder pad regions 111 are connected electrically to the first display region and the second display region respectively.

Specifically, as shown in FIG. 3-1/4-1 and FIG. 3-2/4-2, the solder pad region 111 can be disposed on outside of the first display region and the second display region (a short side away from the bending region). As shown in FIG. 3-3/4-3, the solder pad region 111 can be disposed between the first display region and the second display region. As shown in FIG. 3-4/4-4, the solder pad region 111 can be disposed on outside of the first display region and the second display region, or disposed on inside of the first display region and the second display region, or disposed on outside and inside of the first display region and the second display region respectively. As shown in FIG. 3-5/4-5, the first display region and the second display region share the solder pad region 111, the solder pad region 111 is disposed between the first display region and the second display region, or disposed adjacently to the bending region, or disposed in the bending region.

Overall, the solder pad region 111 cannot be disposed on the same position with the OLED layer 120 and the packaging layer 130.

In the embodiment, a disposition method of the solder pad region 111 can shorten a wire in the OLED layer efficiently and reduce power consumption of the integrated circuit, which can help to improve display quality of the double-side OLED display.

It is comprehensible that a specific position of the solder pad region 111 can be adjusted along a long side or a short side away from the bending region, or within a range of the substrate 110 corresponding to the bending region.

The amount of the solder pad region 111 can be one (FIG. 3-1, FIG. 3-5) or two (FIG. 3-2 through FIG. 3-4).

In FIG. 3-1, the first display region and the second display region of the OLED layer 120 are connected as a whole. The solder pad region 111 is connected electrically to the first region and the second display region of the OLED layer 120 simultaneously. In FIG. 3-5, the first display region and the second display region of the OLED layer 120 are connected by a wire, the solder pad region 111 is connected to the first display region and the second display region respectively. It is comprehensible that the OLED layers are driven by a common integrated circuit in FIG. 3-1 and FIG. 3-5, therefore, images displayed on the first region and the second display region are the same.

FIG. 3-1 can display the same image or various images, for instance, when various images are displayed, different image signals are driven to the first display region and the second display region respectively, when the same image is displayed, a same image signal is driven to the first display region and the second display region respectively. The first display region and the second display region in FIG. 3-5 show the same image. In FIG. 3-5, the first display region and the second display region share the solder pad region 111, areas and resolution of the two display sides are preferable to be the same respectively, and raw drive signal lines and column drive signal lines are connected respectively on the solder pad region 111 and share a terminal.

When the amount of the solder pad region 111 can be one, a control system and a signal input terminal such as a soft circuit board and an integrated circuit can be shared for further reducing costs of integrated circuit consumption.

In FIG. 3-2 through FIG. 3-4, the first display region and the second display region of the OLED layer 120 are independent mutually, the two solder pad regions 111 are connected to the first display region and the second display region respectively. The first display region and the second display region of the OLED layer 120 are driven by separate integrated circuits respectively in FIG. 3-2 through FIG. 3-4, images displayed on the first display region and the second display region can be identical or not.

The two solder pad regions 111 in FIG. 3-4 can be distributed on the same long side, or distributed on two long sides.

It is comprehensible that in the embodiment, an angle formed by the bending region 140 of the double-side OLED display can be determined by materials of the substrate 110, the OLED layer 120 and the packaging layer 130 as well as practical requirements, the first display region and the corresponding second display region except the bending region 140 are parallel, which is not a limitation.

It is comprehensible that a thinning process can be treated on the substrate corresponding to the bending region so as to reduce the thickness.

The overlapped substrate, OLED layer and packaging layer are bended and folded inwards by disposing the bending region according to the double-side OLED display above, the first display region and the second display region of the OLED layer are disposed on two separate flat surfaces to achieve a function of display on two sides. Because the double-side OLED display is formed by bending and folding a single OLED display panel instead of pasting two display panels, which can make the OLED thin and light, reduce time for manufacture and enhance productivity.

The solder pad region is disposed on the substrate corresponding to where is adjacent to the bending region to shorten a wire in the OLED layer to the solder pad region efficiently and reduce power consumption of the integrated circuit, which can help to improve display quality of the double-side OLED display.

When the bending region does not cover the OLED layer or covers the OLED layer and the packaging layer, or the substrate of the bending region is being thinned, a thickness of the bending region can be reduced for convenience of bending.

Referring to FIG. 5, FIG. 5 is a flow chart of a manufacture method of a double-side OLED display according to an embodiment of the disclosure. The manufacture method of a double-side OLED display of the embodiment includes following steps:

S101, forming an OLED layer and a packaging layer on the substrate in sequence.

Specifically, an OLED layer is formed on the substrate, and a packaging layer is formed on a surface of the OLED layer. The OLED layer 120 is applied to stimulate a light-emitting material to irradiate under control of the control system/signal input terminal; the packaging layer is applied to prevent vapor in the air from entering the double-side OLED display and reducing display quality.

A first display region, a bending region and a second display region are disposed correspondingly on the substrate; the bending region is between the first display region and the second display region; the bending region is applied to make the first display region and the second display region opposite.

The OLED layer and the packaging layer at least cover the first display region and the corresponding second display region on the substrate.

Furthermore, the substrate corresponding to the bending region is not covered by the OLED layer or the packaging layer.

For instance, the OLED layer is formed on the first display region and the second display region corresponding to the substrate, packaging is completed on a surface of the OLED layer. Packaging can be thin film packaging and/or outer lid packaging.

Furthermore, the packaging layer further covers the bending region, or the OLED layer and the packaging layer further cover the bending region.

For instance, the OLED layer is formed on the first display region and the second display region corresponding to the substrate, the packaging layer is formed on the surface of the OLED layer and a surface of the substrate corresponding to the bending region; or the OLED layer is formed on the first display region, the bending region and the second display region corresponding to the substrate, and the packaging layer is formed on the surface of the OLED layer.

In other embodiments, a mask plate can be disposed on a solder pad region of the substrate, and an OLED layer and a packaging layer are formed on the substrate correspondingly.

It is comprehensible that in the embodiment, the OLED layer and the packaging layer are disposed on corresponding positions, in other embodiments, the OLED layer and the packaging layer on corresponding positions can be etched after forming the OLED layer and the packaging layer on the substrate, which is not a limitation.

The OLED layer corresponding to the first display region and the OLED layer corresponding to the second display region can be connected or not.

When the OLED layers corresponding to the first display region and the second display region are connected, a solder pad region is disposed on a predetermined position correspondingly, only one control system/signal input terminal is needed to drive the OLED layer to work, images displayed on the first display region and the second display region can be the same or not, which means the double-side OLED display shows a same image or different images. When the OLED layers corresponding to the first display region and the second display region are not connected, two solder pad regions are disposed on the predetermined positions correspondingly, two control systems/signal input terminals are needed to drive the first display region and the second display region of the OLED layer respectively to work, images displayed on the first display region and the second display region can be equal or not.

A position of the solder pad region refers to plan views of positions of a solder pad region in a double-side OLED display according to an embodiment of the disclosure in FIG. 3.

S102, bending the substrate, the OLED layer and the packaging layer towards inside of the substrate, to make the first display region and the second display region on two separate flat surfaces.

The substrate, the OLED layer and the packaging layer are bent towards inside of the substrate with the bending region as a reference point to make the first display region and the second display region on two separate flat surfaces, in order to make the double-side OLED display to show on both sides. Two sections of the substrate after being bent are adjacent, disposed inside of the double-side OLED display.

It is comprehensible that in the embodiment, an angle formed by the bending region of the double-side OLED display can be determined by materials of the substrate, the OLED layer and the packaging layer as well as practical requirements, the first display region and the corresponding second display region except the bending region are parallel, which is not a limitation.

A soft circuit board is pasted on the solder pad region after bending the substrate, the OLED layer and the packaging layer as a whole towards inside of the substrate till a predetermined angle, and connected to an integrated circuit by the soft circuit board, for driving the OLED layer to irradiate by the integrated circuit, in order to make the double-side OLED display to show images on the first display region and the second display region.

According to the previous proposal, the OLED layer and the packaging layer are disposed on the substrate in sequence with the bending region as a reference point, the substrate, the OLED layer and the packaging layer are bent towards inside of the substrate to make the first display region and the second display region on two separate flat surfaces. As the double-side OLED display is formed by bending and folding a single OLED display panel instead of pasting two display panels in a conventional technique, which can make the OLED thin and light, reduce time for manufacture and enhance productivity.

The solder pad region is disposed on the substrate corresponding to where is adjacent to the bending region to shorten a wire in the OLED layer to the solder pad region efficiently and reduce power consumption of the integrated circuit, which can help to improve display quality of the double-side OLED display.

When the bending region does not cover the OLED layer or covers the OLED layer and the packaging layer, or the substrate of the bending region is being thinned, a thickness of the bending region can be reduced for convenience of bending.

Above are embodiments of the disclosure, which do not limit the scope of the disclosure, any modifications, equivalent replacements or improvements within the spirit and principles of the embodiments described above should be covered by the protected scope of the disclosure.

1. A double-side organic light-emitting diode (OLED) display, wherein the double-side OLED display comprises a substrate, an OLED layer and a packaging layer overlapped in sequence; the OLED layer comprises a first display region and a second display region; the double-side OLED display has a bending region, the bending region is applied to bend the double-side OLED display inwards, to place the first display region and the second display region on two separate flat surfaces.

2. The display according to claim 1, wherein the substrate corresponding to the bending region is not covered by the OLED layer.

3. The display according to claim 1, wherein the substrate corresponding to the bending region is not covered by the OLED layer or the packaging layer.

4. The display according to claim 1, wherein a solder pad region is disposed on the substrate, the OLED layer and the packaging layer do not cover the solder pad region; the solder pad region is connected electrically to the OLED layer, applied to paste a soft circuit board; the OLED layer comprises an OLED device.

5. The display according to claim 4, wherein the solder pad region is disposed on a side of the substrate away from the bending region, or disposed on the substrate corresponding to the bending region.

6. The display according to claim 5, wherein the amount of the solder pad region is one or two; when the amount of the solder pad region is one, the solder pad region is connected to the first display region and the second display region electrically; when the amount of the solder pad region is two, the two solder pad regions are connected electrically to the first display region and the second display region respectively.

7. A manufacture method of a double-side organic light-emitting diode (OLED) display, wherein the method comprises:
forming an OLED layer and a packaging layer on the substrate in sequence; wherein a first display region, a bending region and a second display region are disposed on the substrate; the bending region is applied to make the first display region and the second display region opposite;
bending the substrate, the OLED layer and the packaging layer towards inside of the substrate, to make the first display region and the second display region on two separate flat surfaces.

8. The method according to claim 7, wherein the OLED layer and the packaging layer at least cover the first display region and the second display region.

9. The method according to claim 8, wherein the packaging layer further covers the bending region, or the OLED layer and the packaging layer further cover the bending region.

10. The method according to claim 7, wherein a solder pad region is disposed on the substrate; the solder pad region is not covered by the OLED layer or the packaging layer.
